(19) United States
(12) Patent Application Publication
(10) Pub. No.: US 2005/0216816 A1
(43) Pub. Date: Sep. 29, 2005

(54) Error correction code generator, generation method of error correction code, error correction device, and error correction method

(75) Inventors: Tadashi Kojima, Yokohama-shi (JP); Toshihiko Kaneshige, Yokohama-shi (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 10/932,242

(22) Filed: Sep. 2, 2004

(30) Foreign Application Priority Data
Mar. 25, 2004 (JP) 2004-090668

(51) Int. Cl. H03M 13/00

(52) U.S. Cl. 714/758

(57) ABSTRACT

Error correction codes are generated by the respective components of an ECC block, then the codes are added so as to generate an error correction code of the ECC block as a whole. Because error correction codes have linearity, the same results can be obtained by adding the error correction codes after they are calculated separately, as the error correction code calculated as a whole ECC block. The error correction code is calculated by separating the ECC block, thereby the number of times to read/write from/to a memory can be restricted as a whole ECC block, and the amount of data to write/read to/from a memory can be reduced.

### CROSS-REFERENCE TO THE INVENTION

This application is based upon and claims the benefit of priority from the prior Japanese Patent Application No. 2004-090668, filed on Mar. 25, 2004; the entire contents of which are incorporated herein by reference.

### BACKGROUND OF THE INVENTION

1. Field of the Invention

The present invention relates to an error correction code generator, a generation method of error correction code, an error correction device, and an error correction method, to generate an error correction code of an ECC block containing an ID data and a main data.

2. Description of the Related Art

An ECC block containing an ID data and a main data and so on, is used to record/reproduce information on a DVD. An error correction code (ECC) and so on are added to the ECC block, to make it possible to correct the data when some errors are mixed in the data.

Here, there is disclosed a prior art to perform the encoding of an ECC block efficiently (see Japanese Patent Laid-Open Application No. Hei 11-185399).

### SUMMARY OF THE INVENTION

In the above-described prior art, all that the efficiency of a calculation process of codes is increased, but the reduction and so on of writing/reading to/from a memory at the time of the calculation is not achieved. The writing/reading to/from a memory consumes time and power, therefore if the writing/reading to/from a memory can be reduced, the speeding up of the process and the low power consumption can be promoted.

In view of the foregoing, an object of the present invention is to provide an error correction code generator, a generation method of error correction code, an error correction device, and an error correction method in which the amount of writing/reading of data to/from a memory can be reduced.

A. To achieve the above-described object, an error correction code generator according to the present invention, including: an individual error correction code generating unit to generate the error correction codes of the respective plural blocks having one of a plurality of components composing an ECC block; and an ECC code generating unit to generate the error correction code of the ECC block as a whole by adding the generated error correction codes.

To generate an error correction code of an ECC block, error correction codes by the respective components of the ECC block are generated and then added, thereby an error correction code of the ECC block as a whole is generated. Because error correction codes have linearity, they are calculated separately and then added, thereby the same results can be obtained, as the error correction code calculated as a whole ECC block. The ECC block is separated and the error correction code is calculated, thereby the number of times to read/write from/to a memory can be restricted as a whole ECC block, and the amount of data to write/read to/from the memory can be reduced.

(1) The individual error correction code generating unit may include: a first code generating unit to generate a first error correction code based on an ID data composing the ECC block; a second code generating unit to generate a second error correction code based on a main data composing the ECC block; and a third code generating unit to generate a third error correction code based on a scramble data composing the ECC block.

The components of the ECC block is separated into an ID part, a main data, and a scramble data, then the error correction codes are calculated by the respective components, and the codes are added, thereby the error correction code of the ECC block as a whole can be calculated.

(2) The first code generating unit may generate the first error correction code based on the ID data and the error detecting code of the ID data.

The ID data in itself and the error detecting code are put together, thereby the error correction code can be generated.

(3) The second code generating unit may generate the second error correction code based on the main data and the error detecting code of the main data.

The main data in itself and the error detecting code are put together, thereby the error correction code can be generated.

(4) The third code generating unit may have a table representing a correspondence between the scramble data and the third error correction code.

By referring to the table, the error correction code for the scramble data can be generated. The calculation of the scramble data is unnecessary, thereby the generation of the error correction code can be performed more rapidly.

(5) The error correction code generator further including: a recording medium writing unit to write the ECC block having the generated error correction code of the ECC block to a recording medium; a write judgment unit to judge whether a writing process of the ECC block by said recording medium writing unit is successful or not; and a data modification unit to modify the ID data and the scramble data of the ECC block when said write judgment unit judges that the writing process of the ECC block is unsuccessful, and wherein said individual error correction code generating unit further including: a fourth code generating unit to generate a fourth error correction code based on the modified ID data; and a fifth code generating unit to generate a fifth error correction code based on the modified scramble data, and wherein said ECC code generating unit generates the error correction code of the ECC block as a whole by adding the second, fourth, and fifth error correction codes.

In case when the writing operation of data to a recording medium is unsuccessful caused by a defect or the like on a part of the recording medium, it is required to recalculate the ECC block, and record on a new region of the recording medium. In this case, the error correction code corresponding to the main data is used as it is, and the error correction codes corresponding to the ID data and the scramble data are recalculated and added, thereby the recalculation of the error correction code of the ECC block as a whole can be performed.

The recalculation of the error correction code of the main data having a large amount of data is not necessary, thereby the recalculation of the error correction code of the ECC block as a whole can be performed rapidly. As a result, it is not required to prepare the results of the recalculation of the error correction codes in advance, for the case that the writing process of data to the recording medium is unsuccessful.

B. A generation method of an error correction code according to the present invention, including: generating the error correction codes of the respective plural blocks having one of a plurality of components composing an ECC block; and generating the error correction code of the ECC block as a whole by adding the generated error correction codes.

To generate an error correction code of an ECC block, error correction codes by the respective components of the ECC block are generated and then added, thereby an error correction code of the ECC block as a whole is generated. Because error correction codes have linearity, they are calculated separately and then added, thereby the same results can be obtained, as the error correction code calculated as a whole ECC block. The ECC block is separated and the error correction code is calculated, thereby the number of times to read/write from/to a memory can be restricted as a whole ECC block, and the amount of data to write/read to/from the memory can be reduced.

(1) The generating the error correction codes of the respective plural blocks, including: generating a first error correction code based on an ID data composing the ECC block; generating a second error correction code based on a main data composing the ECC block; and generating a third error correction code based on a scramble data composing the ECC block.

The components of the ECC block are separated into an ID part, a main data, and a scramble data, then the error correction codes by the respective components are calculated, and then added, thereby the error correction code of the ECC block as a whole can be calculated.

(2) The first error correction code may be generated based on the ID data and the error detecting code of the ID data.

The ID data in itself and the error detecting code are put together and the error correction code can be generated.

(3) The second error correction code may be generated based on the main data and the error detecting code of the main data.

The main data in itself and the error detecting code are put together and the error correction code can be generated.

(4) The third error correction code may be generated by using a table representing the correspondence between the scramble data and the third error correction code.

By referring to the table, the error correction code for the scramble data can be generated. The calculation of the scramble data is not necessary, thereby the error correction code can be generated rapidly.

(5) The generation method of an error correction code, further including: attempting to write the ECC block having the generated error correction code of the ECC block to a recording medium; judging whether said attempting to write is successful or not; and modifying the ID data and the scramble data of the ECC block when said attempting to write is judged as unsuccessful, and wherein said generating the error correction codes of the respective plural blocks further including: generating a fourth error correction code based on the modified ID data; and generating a fifth error correction code based on the modified scramble data, and wherein the second, fourth, and fifth error correction codes are added and the error correction code of the ECC block as a whole is generated.

In case when the writing operation of data to a recording medium is unsuccessful caused by a defect or the like on a part of the recording medium, it is required to recalculate the ECC block, and record it on a new region of the recording medium. In this case, the error correction code corresponding to the main data is used as it is, and the error correction codes corresponding to the ID data and the scramble data are recalculated and added, thereby the recalculation of the error correction code of the ECC block as a whole can be performed.

The recalculation of the error correction code of the main data having a large amount of data is not necessary, thereby the recalculation of the error correction code of the ECC block as a whole can be performed rapidly. As a result, it is not required to prepare the results of the recalculation of the error correction codes in advance, for the case that the writing process of data to the recording medium is unsuccessful.

C. An error correction device according to the present invention, including: an ID detecting unit to detect an ID data from an ECC block including an error correction code; a de-scramble unit to de-scramble the ECC block with the detected ID data; and an error detecting unit to detect an error of the ECC block by the EDC calculation process based on the de-scrambled ECC block.

The processes of the ID detection, de-scrambling, the error detection are performed sequentially, and the ECC block is processed. By performing the processes sequentially, the number of times to read the original ECC block from a memory can be reduced.

D. An error correction method according to the present invention, including: detecting an ID data from an ECC block including an error correction code; de-scrambling the ECC block with the detected ID data; and detecting an error of the ECC block by the EDC calculation process based on the de-scrambled ECC block.

The processes of the ID detection, de-scrambling, the error detection are performed sequentially, and the ECC block is processed. By performing the processes sequentially, the number of times to read the original ECC block from a memory can be reduced.

### BRIEF DESCRIPTION OF THE DRAWINGS

FIG. 1 is a schematic view representing a generation method of an ECC block according to an embodiment of the present invention.

FIG. 2 is a schematic view representing a configuration of the ECC block.

FIG. 3 is a schematic view representing a configuration of a data frame.

FIG. 4 is a schematic view representing an outline of contents of a process until a physical sector is generated in a DVD system.

FIG. 5 is a schematic view representing a data frame before a scramble process.

FIG. 6 is a schematic view representing an ECC block after an interleave process.

FIG. 7 is a schematic view representing a recording frame.

FIG. 8 is a schematic view representing the physical sector.

FIG. 9 is a block diagram showing contents of a process until the physical sector is generated in the DVD system.

FIG. 10 is a block diagram representing an outline of contents of a process until a signal is recorded on a recording medium in the DVD system.

FIG. 11 is a block diagram representing contents of a process of reading/writing from/to a memory in a recording operation according to an embodiment of the present invention.

FIG. 12 is a block diagram representing contents of a process of reading/writing from/to a memory in a recording operation shown in FIG. 9.

FIG. 13 is a view showing a relation of data allocation at the time of block-slip recording.

FIG. 14 is a view representing a correspondence of data to respond to a block-slip by creating a recording data in advance.

FIG. 15 is a block diagram representing contents of a process of reading/writing from/to a memory in a block-slip process shown in FIG. 14.

FIG. 16 is a view showing a configuration of a scramble data generator in the DVD system.

FIG. 17 is a view showing a system configuration in which a PO and a PI generated only from scramble data are recorded on a ROM in advance according to an embodiment of the present invention.

FIG. 18 is a view representing contents of a process of writing/reading to/from a memory in a normal reproducing operation.

FIG. 19 is a block diagram representing contents of a process of writing/reading to/from a memory in a reproducing operation according to an embodiment of the present invention.

FIG. 20 is a block diagram in which a miss correction detection by using syndromes as error flags is combined to FIG. 19.

### DESCRIPTION OF THE EMBODIMENTS

Hereinafter, embodiments of the present invention will be described in detail with reference to the drawings.

(Recording of Data on a Recording Medium: Generation of an ECC Block)

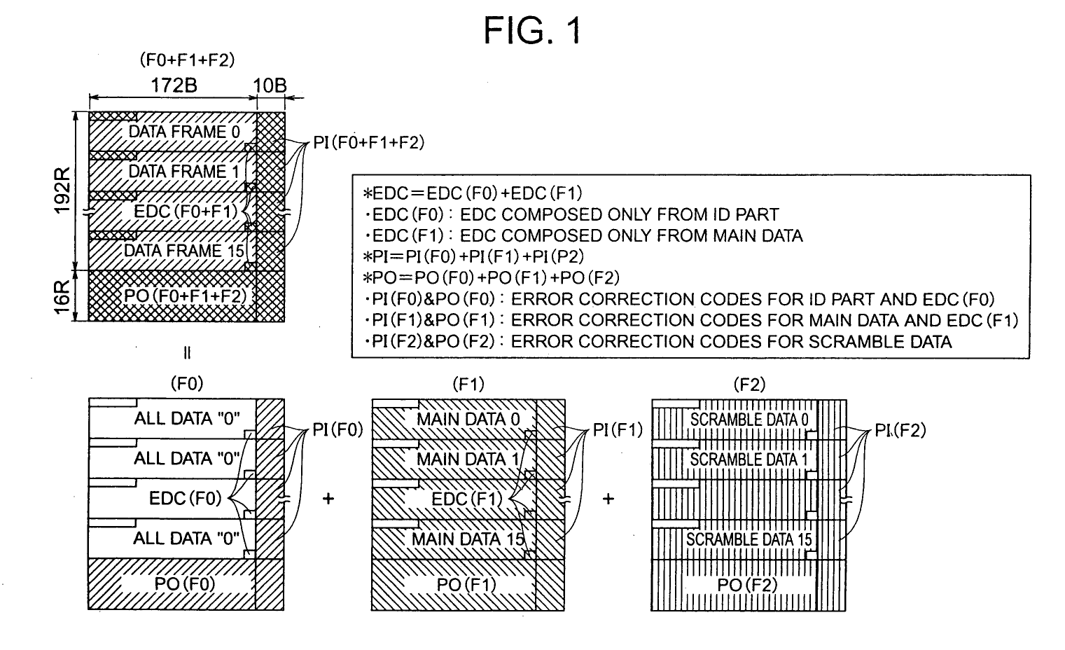

FIG. 1 is a schematic view representing a generation method of an ECC block (F0+F1+F2) according to an embodiment of the present invention. As it is described later, the ECC block (F0+F1+F2) is generated from three ECC blocks (F0), (F1), and (F2).

Incidentally, the ECC block (F0+F1+F2) generated by the procedure shown in FIG. 1 in itself is the same as an ECC block used in DVD.

First, a configuration of the ECC block (F0+F1+.F2) is shown.

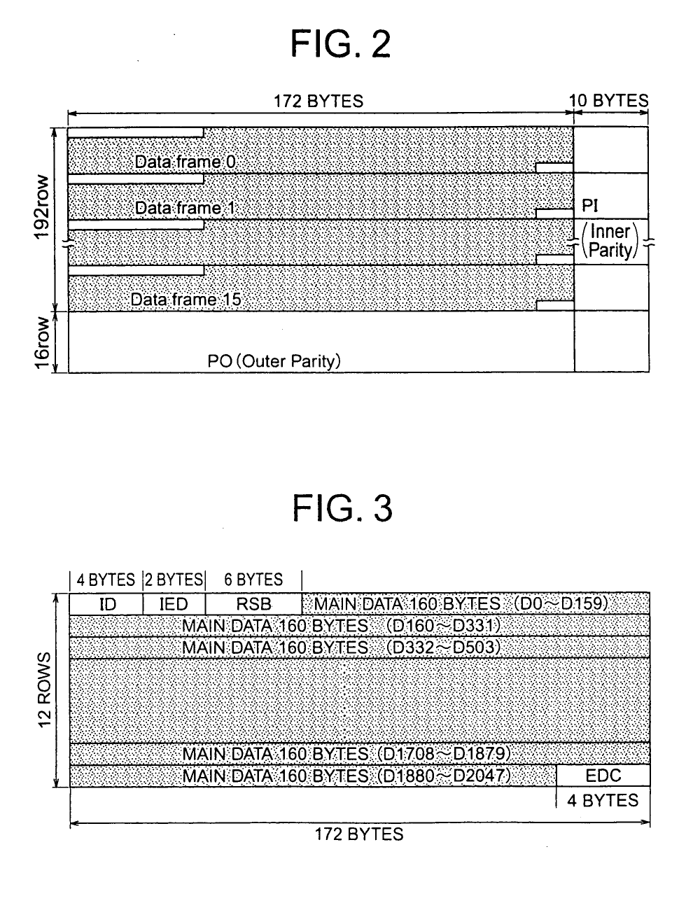

FIG. 2 is a schematic view representing a configuration of the ECC block.

The ECC block is composed of sixteen sets of data frames 0 to 15 being combined, and inner parities PI and an outer parity PO are added thereto as error correction codes. The outer parity PO of 16 bytes (1 byte=1 row) is added to each column (vertical direction) of the ECC block, and inner parities PI of 10 bytes are added to the respective rows (lateral direction). The outer parity PO of 16 rows (16 bytes) are allocated in such a manner that one row (byte) is dispersed to every 12 rows (each sector).

FIG. 3 is a schematic view representing a configuration of the data frame.

The data frame is composed of 12 rows (1 row=172 bytes). On a first row, a sector identifier (ID data, IDentification data) which is composed of a sector number and sector information is allocated, and subsequently there are an ID error detecting code (IED), auxiliary data (RSB) used as a control signal and so on, and a main data region of 2 Kbytes (2048 bytes) thereafter. On the end of a last row, an error detecting code (EDC) for the main data is added.

A scramble process is performed to the main data (main information) so as to add a random signal to the main data. The scramble process is carried out even when the contents of the main data are “all ‘0’”, so as to prevent the recording data from being a repeat of the same pattern. This is because there is a concern of occurring a problem such that a tracking servo error signal cannot be accurately detected and so on, due to a cross talk or the like of adjacent tracks on a optical disk and so on.

Incidentally, the region where the sector identifier (ID), the ID error detecting code (IED), and the auxiliary data (RSB) are recorded is referred to as an ID part (or ID region) hereinafter.

Here, a generation procedure of the ECC block (F0+F1+F2) is explained, by returning to FIG. 1.

As it is already mentioned, the ECC block (F0+F1+F2) is constituted from the data frames composed of the ID part, the scrambled main data, and the EDC, aggregated together and the error correction codes PO/PI are added thereto.

In the present embodiment, the ECC block (F0+F1+F2) is generated by adding three ECC blocks (F0), (F1), and (F2). On the contrary, the ECC block (F0+F1+F2) can be divided into the three ECC blocks (F0), (F1), and (F2).

These three ECC blocks (F0), (F1), and (F2) correspond to each data type of the ECC block (F0+F1+F2).

The ECC block (F0) is composed of the ID part, and an EDC (F0), a PO (F0), and a PI (F0), generated only from the ID part. The EDC (F0), the PO (F0), and the PI (F0) are generated to have the value of “0” in the region other than the ID part (region for main data).

The ECC block (F1) is composed of the main data, and an EDC (F1), a PO (F1), and a PI (F1) generated only from the main data. The EDC (F1), the PO (F1), and the PI (F1) are generated to have the value of “0” in the region other than the main data (ID part).

The ECC block (F2) is composed of a PO (F2) and a PI (F2) generated only from the scramble data. That is to say, the ID part and the EDC part thereof have the value of “0”.

It depends that the calculations to generate the codes of the EDC, the PO, and the PI have linearity. As a encoding having such a linearity, a Read-Solomon code can be cited.

Usually, the calculation is not performed dividedly as stated above, but the scramble process and the addition of error correction codes PO/PI are performed as a whole ECC block. As the error correction codes have linearity, the same ECC block can be generated if it is processed after division and then added as in the present embodiment, or it is processed directly (without division).

According to the present embodiment, the ECC block is generated in such a manner that the codes are generated by the respective data type of the ECC block, and then the generated codes are added. Thereby the input/output amount of data composing the ECC block between a memory can be reduced. As a result, a high speed processing and a low power consumption can be realized. The details will be described later.

(An Example for Reference: A Process of an ECC Block as a Whole)

Here, contents of a process until a physical sector being a recording signal in a DVD system is generated, is described for reference.

In general, when information data and so on are recorded on a recording medium, it is difficult to completely prevent the occurrence of data damage caused by a defect or the like. Therefore an error correction code is added to recover the data. And an error detecting code is added before the error correction code is added, because it is possible that a miss correction may occur during an error correction process.

Further, in a disc-shaped recording medium (what is called as a disk) and so on, a cross talk between adjacent tracks is inevitable. In this case, when the recording signals between adjacent tracks repeat the same pattern, it may become difficult to realize a stable tracking servo. Therefore a scramble process may be performed to the data.

In this manner, many processes are performed until a signal is recorded on the recording medium, such that various data are added to a main data, or data are processed.

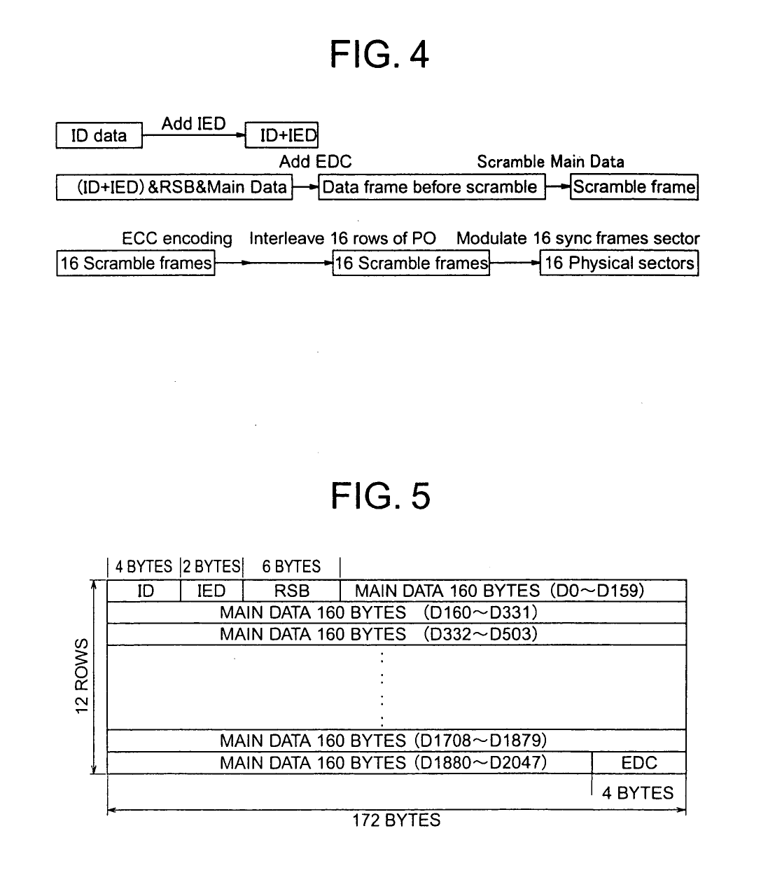

FIG. 4 is a schematic view representing an outline of contents of a process until the physical sector being the recording signal in the DVD system is generated. The contents of the process is as indicated below.

An ID error detecting code IED corresponding to ID being a sector identifier of each physical sector, is generated and added to the ID.

An error detecting code (EDC) for the sector identifier (ID), the ID error detecting code (IED), an auxiliary data (RSB), and the main data is generated and added to the ID, IED, RSB, and the main data, thereby a data frame is created.

FIG. 5 is a schematic view representing the data frame (the data frame before scramble process) being generated at this time.

Thereafter, a scramble process is performed, in which a random signal being generated by a random generator based on a part of ID, is added to the main data. Incidentally, the scramble processed data frame is represented in FIG. 2 being already described.

Thereafter, the scrambled data frames are gathered sixteen sets, thereby an ECC block is constituted, then error correction codes (outer parity PO, inner parity PI) are added.

The ECC block (ECC block before an interleave process) constituted by this way is represented in FIG. 3 being already described, and it corresponds to the ECC block (F0+F1+F2) in FIG. 1.

The outer parity PO of the ECC block is interleaved into 16 rows and sixteen sets of recording frames are generated.

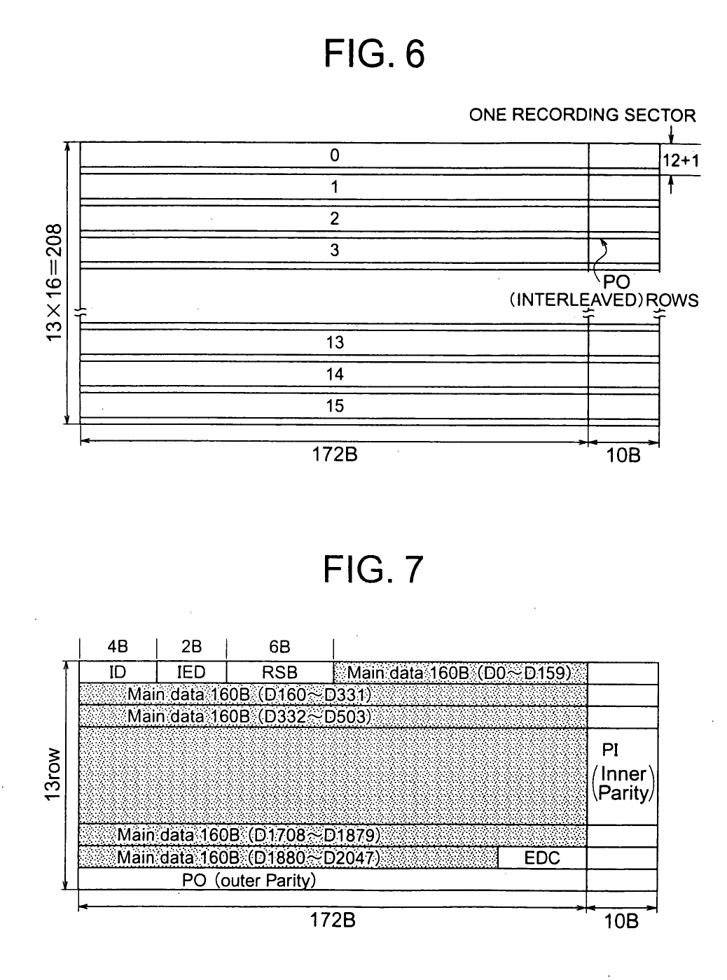

FIG. 6 is a schematic view representing the ECC block after an interleave process.

FIG. 7 is a schematic view representing the recording frame created in this manner.

Each row of the recording frame is divided into two sync frames, a synchronous signal is added on a beginning of each sync frame, and a data is modulated, thereby it becomes a channel bit stream.

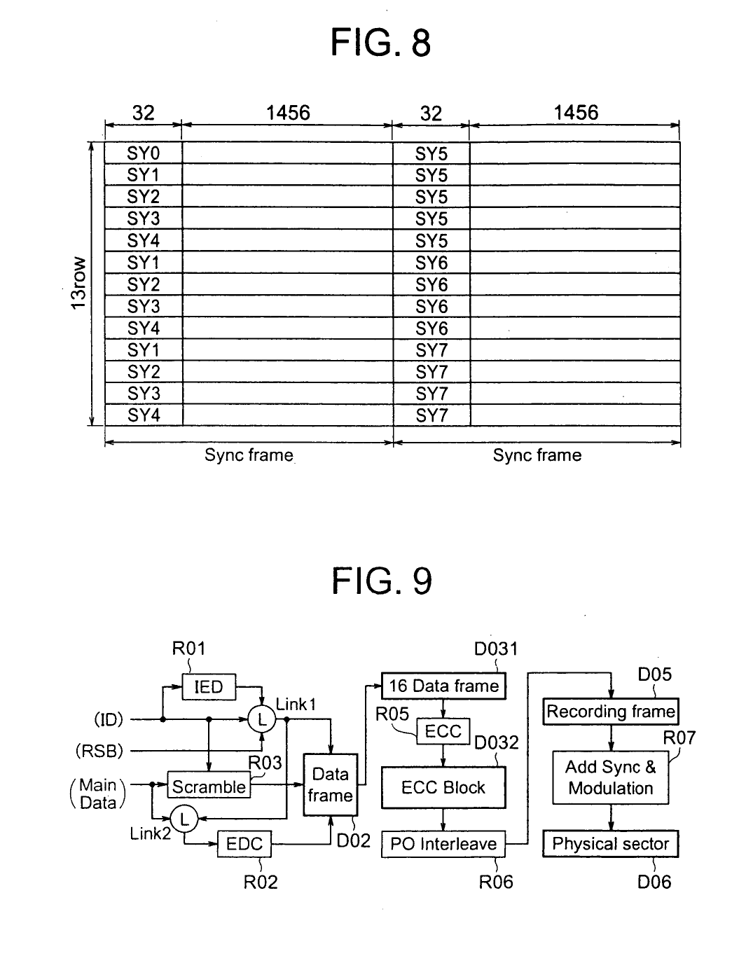

FIG. 8 is a schematic view representing the physical sector being created in this manner.

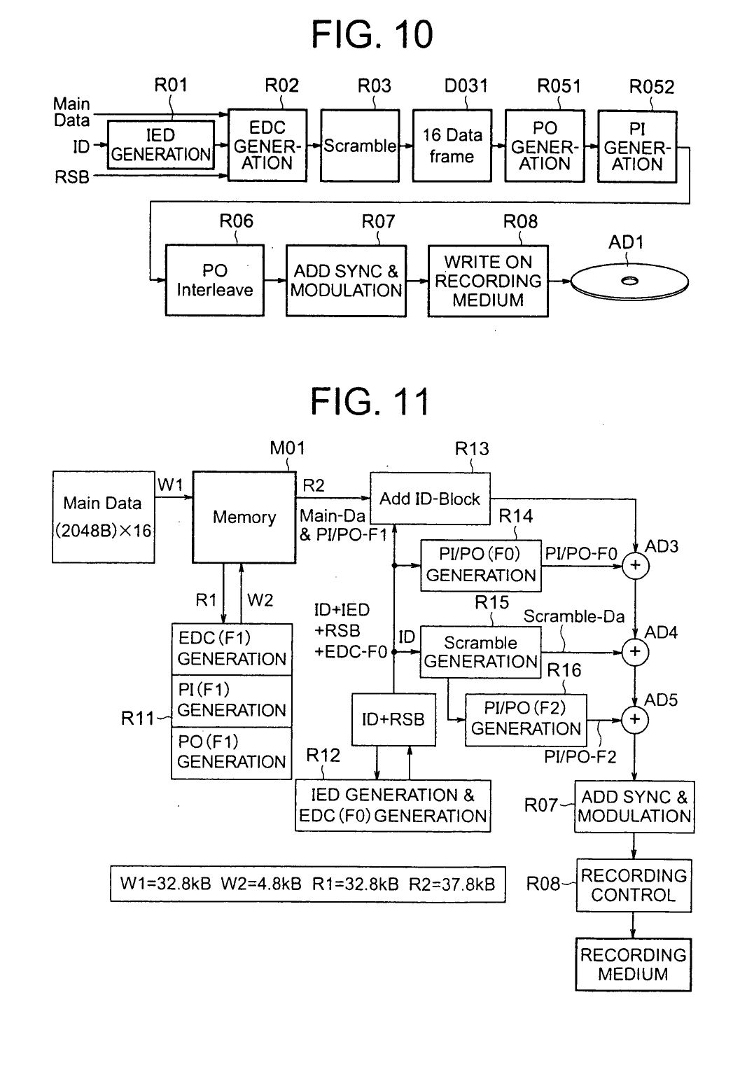

FIG. 9 is a block diagram showing contents of a process until the physical sector is generated in the DVD system. Further, FIG. 10 is a block diagram representing an outline of contents of a process until a signal is recorded on the recording medium in the DVD system. Incidentally, FIG. 9 and FIG. 10 represent substantially the same contents.

An IED is generated from an ID at an IED generation unit (R01), and the IED is linked with a RSB at a linkage unit (Link1). The linked data are sent to a data frame generation unit (D02) and a linkage unit (Link2). The linked data is linked with a main data at the linkage unit (Link2), and an EDC is generated at an EDC generation unit (R02). Meanwhile, a scramble process is performed to the main data at a scramble unit (R03), and the scrambled data are sent to the data frame generation unit (D02). The data frames being combined at the data frame generation unit (D02) are aggregated up to sixteen sets at a 16 data frame aggregating unit (D031). Thereafter they are sent to an ECC generation unit (R05) and added error correction codes (PO & PI), thereby an ECC block (D032) is generated.

At a PO interleave unit (R06), POs are dispersedly allocated on a plurality of rows of the ECC block (D032). At a recording frame generation unit (D05), a recording frame is generated from the ECC block. Next, in an add sync & modulation unit (R07), each row of the recording frame is divided into two parts, then a synchronous signal (Sync) is added on a first part thereof, and the data is modulated, thereby it becomes a channel bit stream and a physical sector (D06) to be a recording signal is generated.

(Amount of Writing/Reading of Data to/from a Memory)

FIG. 11 is a block diagram representing contents of a process of reading/writing from/to a memory in a recording operation according to an embodiment of the present invention. In the view, a process corresponding to FIG. 1 is performed.

Sixteen main data (2048 bytes*16) are written to a memory (M01).

The main data are read from the memory (M01), then an EDC (F1), a PO (F1), and a PI (F1) constituted only from the main data are generated (R11), thereafter it is recorded on the memory (M01).

An IED is generated from an ID, and then an EDC (F0) constituted only from the ID, the IED, and a RSB is generated (R12).

The main data are read from the memory (M01), then add the ID part, thereby the ECC block (F1) is generated (R13).

A PO (F0) and a PI (F0) are generated (R14) only from the ID part and the EDC (F0), and add them to the PO (F1) and the PI (F1) (AD3).

A scramble data is generated from the ID (R15), and add them to the main data (AD4).

A PO (F2) and a PI (F2) are generated only from a scramble data (R16), and add them to the PO/PI part (AD5).

As described above, an ECC block (F0+F1+F2) is generated.

Thereafter, a synchronous signal is added to the ECC block (F0+F1+F2) and it is modulated, then a physical sector is generated (R07). The physical sector (modulated data) is recorded on a recording medium (R08).

During the process in FIG. 11, PO/PI generation calculation processes occur for the main data part, the ID part, and the scramble data part.

However, the PO/PI for the ID part can be generated by using a relatively easy calculation. This is because the data amounts of the ID part and the EDC (F0) existing on each data frame are small (the former data is 12 bytes), and all the others are “0” data.

Besides, the PO/PI for the scramble data can also be generated by a relatively easy calculation. In the DVD system, only 16 patterns of the scramble data are existing, and the same calculation process using a code generation polynomial, used for the main data to be calculated in each case, is not necessary. As an easy way, the PO/PI values being calculated in advance are recorded on a ROM or the like, and use them selectively. Details will be described later.

A number of times of reading/writing from/to the memory by a unit of 32 Kbytes to 37 Kbytes are three times (writing is once, readings are twice), and the processing steps can be reduced drastically, thereby the speeding up and the low power consumption can be expected.

### COMPARATIVE EXAMPLE

A comparative example of the process in FIG. 11 is shown.

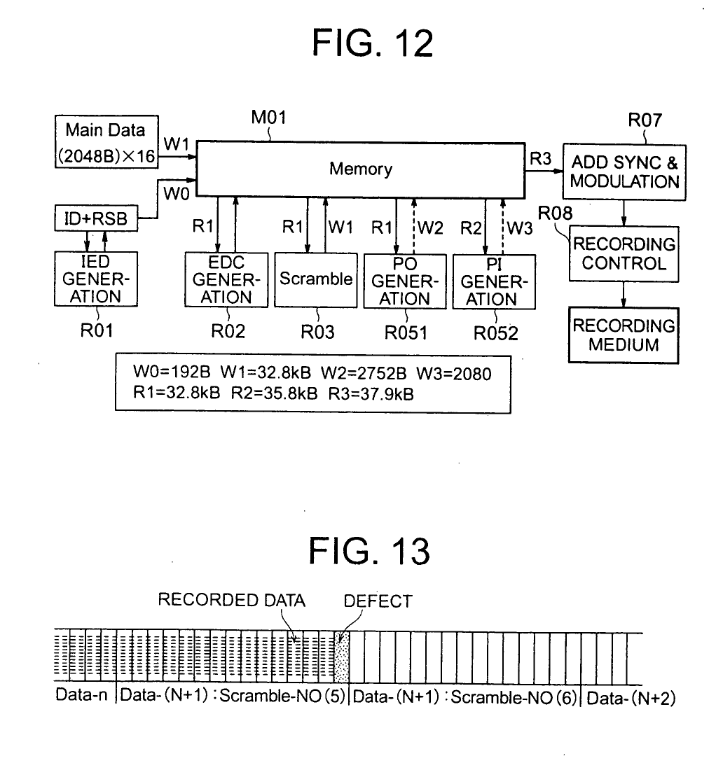

FIG. 12 is a view representing a relation of each calculation process centered on a memory (M01) used for a data cache and for a buffer storage. Hereinafter, a generation process of the physical sector shown in FIG. 9 is explained.

Sixteen sets (32.8 Kbytes) of main data of 2048 bytes are written to the memory (M01).

An IED is generated for an ID, and data of sixteen sets of ID part (ID+IED+RSB) of 192 bytes are written to the memory (M01).

The ID part and the main data are read from the memory (M01) as a unit of a data frame, and sixteen sets of an EDC for each data frame are generated.

Only the main data are read from the memory (M01), then performed a scramble process, and the scrambled data are written to the memory (M01).

Each column of the ECC block of 192 bytes*172 columns are read from the memory (M01), then the PO (2752 bytes) is generated, and it is written to the memory (M01).

Each row of the ECC block of 172 bytes*208 rows are read from the memory (M01), then the PI (2080 bytes) is generated, and it is written to the memory (M01).

A recording frame is made by adding the PIs and one row of the PO to every data frame, and sixteen sets of the recording frames are sequentially read, added synchronous signals, performed modulation processes, and recorded on a recording medium at a recording control unit (R08).

From the above description, it turns out that in the generation process of the physical sector from one ECC block in the recording operation (comparative example), the recording and the reading operations of data by a unit of 32 Kbytes to 38 Kbytes are performed seven times as a total. This may be a bottleneck to realize the speeding up of the calculating process and the low power consumption under a high speed operation.

On the contrary, as shown in FIG. 11, the exchange of data between the memory and each calculation unit for encoding can be reduced drastically in the present embodiment. This can be realized by using the characteristic that the error detecting code and the error correction code are linear codes, the respective codes of the EDC, the PO, and the PI are divided by a unit of their original source data, calculated for generation, and performed additional process.

(Block-Slip Processing)

By the way, a block-slip recording is performed in a defect management system of a video recording standard.

FIG. 13 is a view showing a relation of data allocation at the time of block-slip recording on a certain track.

Next to a “Data−(n)”, a “Data−(n+1)” is recorded. When a defect is found on a recording region of a recording medium which corresponds to a last physical sector region of the “Data−(n+1)”, the “Data−(n+1)” is recorded on the next block recording region.

At this time, contents of a scramble process is determined by a physical ID of a recording track. Therefore, the data “Data−(n+1)” which is slipped (the ID is changed) and recorded, is re-scrambled and as a result, the PO/PI are also re-calculated.

In FIG. 13, the “Data−(n+1)” recorded on a defected region is scrambled with a “Scramble-NO (5)”. On the contrary, the “Data−(n+1)” which is slipped and recorded is scrambled with a “Scramble-NO (6)”, and the PO/PI are calculated by the scrambled data “Data−(n+1)” and then recorded.

To generate a recording data for a slip recording, the re-calculation should be performed in a short time and the normal calculation device is too late in terms of time.

Consequently, a recording data having a modified scramble value is created in advance as a reserve data, thus a rapid response is possible in case a slip recording is occurred. A system like this is called as a preparative respond system.

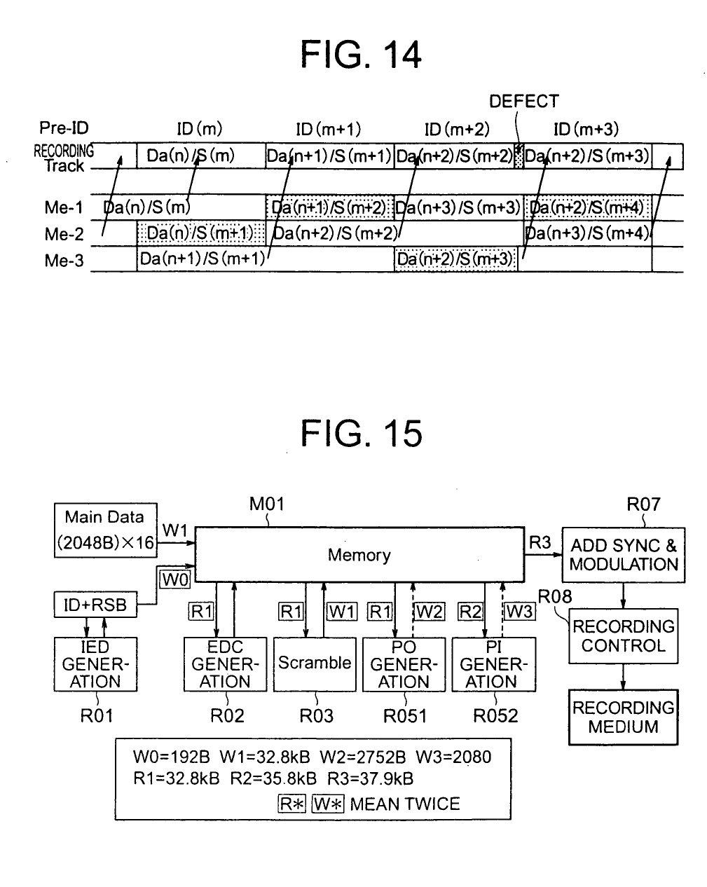

FIG. 14 is a view showing a correspondence of data in the preparative respond system.

Three planes of storage area for recording data are prepared in a memory. That is to say, other than a data storage plane currently used for a recording, a data storage plane having a modified scramble value to respond to the occurrence of the slip recording, and a data storage plane for a next block for the case the slip recording is not occurred, are prepared. In this manner, the slip recording becomes possible by adding two sets of recording data.

FIG. 14 represents a case when an ID (m+2) among ID (m) to ID (m+3) being IDs (Pre-ID) of recording tracks, has a defect. A recording data in a storage memory and a recording data used for an actual recording are indicated by arrows.

In a recording region ID (m), a scrambled data (Da(n)/S (m)) of a data (Da (n)) is recorded. Here, the “n” represents a data number, and the “m” represents a scramble number.

In a recording region (ID (m+1)), a scrambled data (Da (n+1)/S (m+1)) of a data (Da (n+1)) is recorded.

In a recording region (ID (m+2)), a scrambled data (Da (n+2)/S (m+2)) of a data (Da (n+2)) is recorded under normal conditions. However, a defect in the recording region (ID (m+2)) is detected during the recording process, therefore the recording of the data (Da (n+2)) on this recording region is not completed.

In a recording region (ID (m+3)), a scrambled data (Da (n+2)/S(m+3)) of a data (Da (n+2)) is recorded. That is to say, a slip recording of the data (Da (n+2)) is performed on the recording region (ID (m+3)).

To perform the process shown in FIG. 14, two sets of recording data blocks being performed different scramble processes are prepared for one data block. One of these recording data blocks is recorded and the other is deleted as an unnecessary data. In such a processing method, the scramble process or a calculation process for an error correction code becomes twice, and many more read/write processes from/to the memory and the calculation processes are required than the process shown in FIG. 12.

FIG. 15 is a block diagram representing contents of a process centered on a memory within a process in FIG. 14. Compared to FIG. 12, the processing amount of EDC generating calculations, scramble processes, PO/PI generations in FIG. 15 becomes twice, and the recording and reading operations of data by a unit of 32 Kbytes to 38 Kbytes are performed twelve times in total.

On the contrary, in the present embodiment, by using the characteristic that an error detecting code and an error correction code have linearly codes, the respective codes of an EDC, a PO, and a PI and soon are divided by a unit of original source data to generate by calculation, and additional processes are performed. Consequently, the exchange amount of data between a memory and calculation units for encoding can be drastically reduced. Concretely speaking, in the process shown in FIG. 11, the number of times of reading/writing from/to a memory by a unit of 32 Kbytes to 37 Kbytes are three times (writing is once, readings are twice), and the process amount becomes a quarter of the comparative example shown in FIG. 15. As a result, processing steps can be drastically reduced, and the speeding up and the low power consumption can be realized.

That is to say, in the present embodiment, error correction codes (PO, PI) of an ECC block can be recalculated after a slip process occurs actually. Error correction codes of an ID and a scramble data is recalculated, and add them to a already calculated error correction code of a main data, thereby an error correction code of the ECC block as a whole can be recalculated. The recalculation of the error correction code of the main data having a large amount of data is not required, therefore the error correction code of the ECC block as a whole can be recalculated rapidly. In addition, the slip process does not occur so frequently, therefore the increase of the processing amount caused by the occurrence of the slip process does not matter so much.

Incidentally, as it is already mentioned, the scramble data can be recorded on a ROM in advance, then the calculation of the scramble data becomes unnecessary.

(Generation of a Scramble Data)

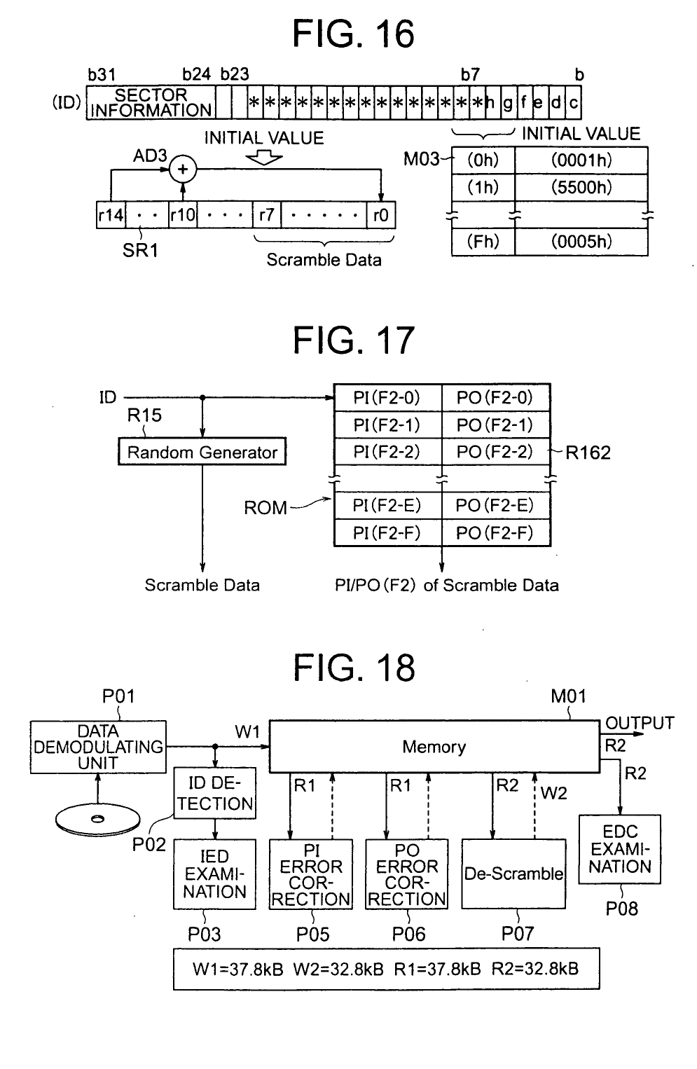

FIG. 16 is a view showing a configuration of a scramble data generator in the DVD system. In a DVD standard, it is prescribed that a random signal is generated by a random number generator with 15-stages of shift register, and it is superposed and added to a main data, thereby a scramble process is performed. An initial value of the random number generator is determined by four bits of b3 to b7 within the ID of the corresponding data frame. Accordingly, types of scramble data exist sixteen (fourth power of two) patterns.

FIG. 17 is a view showing a system configuration in which a PO (F2) and a PI (F2) generated only from scramble data are recorded on a ROM in advance, so as to be selectively used by ID information, according to an embodiment of the present invention.

PIs and POs are recorded on a ROM. An address of the ROM corresponds to the type of scramble data. As a result, the PO and the PI can be obtained from the type of the scramble data.

Consequently, a calculation of the PO (F2) and the PI (F2) of the scramble data becomes unnecessary.

(Reproducing of Data from a Recording Medium: Extract of Data from an ECC Block)

Generation processes of recording data are explained above. A basic concept of the present embodiment is using linearly characteristics of generated codes. That is to say, a data block composed of a plurality of data is divided and processed by the respective data types, and combine them by the addition of codes, thereby objective recording signals can be obtained.

Even on a reproducing operation, the process flow can be reduced by implementing this concept.

FIG. 18 is a view showing contents of a process of writing/reading to/from a memory in a normal reproducing operation. The operation is briefly described.

A signal read from a recording medium is symbol-synchronized by a frame/block synchronization at a data demodulating unit (P01), thereby it is converted from a channel bit stream to a symbol data (in general, a byte data symbol).

At an ID detecting unit (P02), ID information is detected from a data stream. The detected ID information is performed a reliability check by IED at an IED examination unit (P03), and then fixed. By using this ID information and information of a frame/block synchronization, the position to write a data by a unit of an ECC block is specified in a memory (M01), and a data is recorded.

The data written to the memory (M01) is read in sequence at a PI error correction unit (P05), and an error correction process of inner parity PI series for error correction is performed. At this time, an error flag is generated for an error correction impossibility series, and it is kept as error flag information.

Next, all data is read in sequence at a PO error correction unit (P06), and an error correction process of outer parity PO series for error correction is performed. In this case, the error flag generated at the former inner parity PI series for error correction is used, thereby an ability of the error correction process is improved. That is to say, an error position is specified by the error flag and an error pattern is extracted by the correction calculation, thereby the accuracy of the error correction process is improved. Incidentally, an error flag for an error correction impossibility series is also generated in the PO series as well as in the PI series, and it is kept as error flag information.

Here, the error correction process of the PI series may be performed again. In general, when a product code is adopted as an error correction system, the error correction process is possible to perform repeatedly, thereby the error correction ability can be improved.

However, to achieve this effect, it is required to read a data every time when the error correction process is performed, and detect a syndrome to extract error information. To read and process the contiguous data in real time, it is required to perform an error correction process of a block within a limited time. Accordingly, the repeated error correction process may be a cause to set limits to the reading speed. Besides, all data is required to be read every time, therefore it goes against the low power consumption.

After the error correction process is completed, only the main data is read again at a de-scramble unit (P07), to perform a de-scramble process, thereafter records the data on the memory as an original correct data. The de-scramble data written to the memory is read to an EDC examining unit (P08) by a unit of data frame, and an error detection of data is performed if any miss correction or the like is existing or not.

By the above-described successive operations, a final data is stored on the memory, and the data is outputted according to request from external. The number of times of writing/reading to/from a memory by a unit of 32 Kbytes to 37 Kbytes is required to be at least seven times in the above-described FIG. 18.

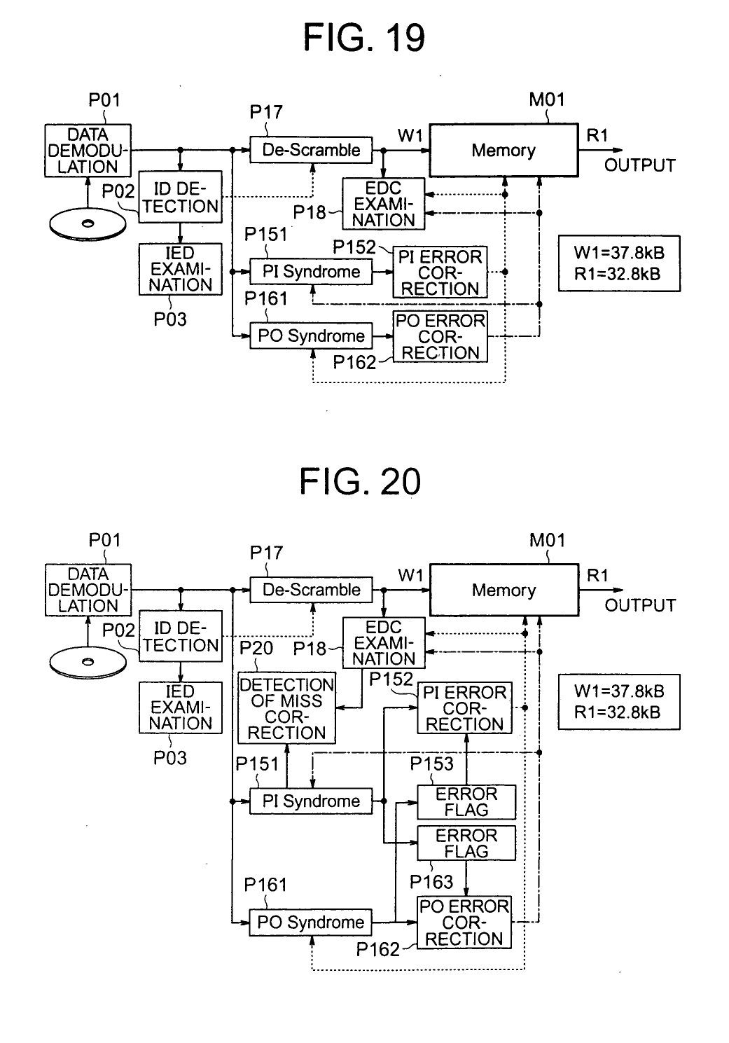

FIG. 19 is a block diagram representing contents of a process of writing/reading to/from a memory in a reproducing operation according to an embodiment of the present invention.

As it is the same as the system shown in FIG. 18, a signal read from a recording medium is demodulated at a data demodulating unit (P01), and becomes a symbol data. Data frames of the symbol data is separated and identified by using a frame synchronization signal or the like, and an ID part is extracted at an ID detecting unit (P02). ID information of the extracted ID part is IED checked at an IED examining unit (P03), and the reliability is secured.

By using this ID information, a de-scramble unit (P17) is operated, and the de-scrambled data is written to a memory (M01).

Data from the data demodulating unit (P01) are sent to a PI syndrome unit (P11) and a PO syndrome unit (P161) in parallel with they are sent to the de-scramble unit (P17), and syndromes using error patterns of error correction series are generated in the respective units. Meanwhile, the data being de-scrambled at the de-scramble unit (P17) are sent to an EDC examining unit (P18) in parallel with they are written to the memory (M01), and an error detection by a unit of data frame is performed.

At this time, if a part of data has an error, the results of PI, PO syndromes and the EDC do not become “0”. In other words, the syndrome of error correction series and an EDC judgment of data frames relating to an error occurrence show the values other than “0”.

Then, a series having a value of PI syndrome other than “0” is selected at a PI error correction unit (P152), and an error correction calculation is performed, thereby a position of an error symbol and an error pattern are extracted. An error correction process is performed by adding the error pattern to a specified data read from the memory (M01) based on the position of the extracted error symbol. The corrected data is written to the original position on the memory (M01).

In addition to the above-described operation, the values of the specified PI syndrome is set as “0”, and send it to the PO syndrome unit (P161) side together with the error symbol position and error pattern information, to perform a syndrome generation calculation. That is to say, a PO error correction series relating to the error symbol position is selected, and a syndrome calculation process on the PO side is performed. The generated syndrome of the PO side is corrected by adding to the specified PO syndrome, then a new syndrome of an error correction series containing the error corrected symbol is generated.

Besides, the PI error correction unit (P152) send the error symbol position and error pattern information to the EDC examining unit (P18). At the EDC examining unit (P18), the correction process of data is performed by EDC calculating to the EDC of the data frame relating to the position information, based on the sent position information and the error pattern data, and adding the calculated EDC to the first detected value.

The operation of the PI error correction process is repeated, and after error corrections for all PI series are completed, the next error correction process at a PO error correction series side is performed. That is to say, as same as the case of the PI side, the PO error correction series in which a syndrome having the value other than “0” is detected, is specified from PO syndromes, and an error correction calculation is performed, thereby an error symbol position and an error pattern is extracted at a PO error correction unit (P162). And a specified data is read from the memory (M01), then an error correction process is performed by adding the error pattern, thereafter the data is written back to the memory (M01) again.

In addition, the PO error correction unit (P162) sets the values of the specified PO syndrome to be “0”, and send it to the PI syndrome unit (P151) side together with the error position and error pattern information. As a result, the syndrome of the PI series relating to the specified PO syndrome is corrected.

Besides, the PO error correction unit (P162) sets the value of the specified PO syndrome to be “0”, and send it to the EDC examining unit (P18) together with the error position and error pattern information. As a result, the EDC value of the data frame relating to the specified PO syndrome is corrected.

Further, in the PI and PO error correction processes, when the value of the opposite syndrome is other than “0”, the error flag is set and it can be used to perform a disappearance correction process.

By performing the above-described operations, together with the writing operation of data to the memory (M01), bases of the PO and PI syndromes are extracted, thereby, as a data to be read for the error correction process, only the error symbol is enough. Consequently, different from a normal system to read all data for detecting the PO and the PI syndromes regardless of the presence/absence of an error symbol, the number of times of the data reading is reduced by approximately a hundredth part, in the present embodiment.

In the normal DVD system, an EDC is generated by a data before scramble, and a PO and a PI being error correction codes are generated by a scrambled data. For this reason, in the normal DVD system, the amount of input/output of data to/from a memory becomes large, restricted by the processing order.

Further, a reliability of a de-scramble process is tolerated by a reliability of an ID detection. On this account, by upgrading the reliability of the ID detection, the deterioration of reliability of data, when the de-scramble process is performed before the error correction process, can be prevented.

Besides, even in the middle of the error correction process, the EDC value of the objective data frame should be “0” when the error symbol of each data frame has the value of “0”, from the status of the syndrome of the PI series. On this account, when the error symbol has the value other than “0”, it can be judged as the miss correction is occurred, thereby the following error correction process can be restrained.

In the present embodiment, the number of times of reading/writing from/to a memory by a unit of 32 Kbytes to 37 Kbytes is once for each (the total is twice).

Further, such a memory map can be adopted that a part of the memory is exclusively used for storing the data of the ID series and the control series, and the other main part are used for storing main data by a unit of 2048 bytes. Thereby, the utilization efficiency of the memory can be improved.

In a block diagram shown in FIG. 20, making use of an error flag for a disappearance correction processing of a syndrome, a detection of a miss correction of each data frame is performed by the PI syndrome unit (P151) and the EDC examining unit (P18).

Hereinabove, the following advantages can be enjoyed in the above-described embodiment.

1. An ECC block to be used for data recording/reproducing system on a recording medium, is sectionalized by specific type of signal (data), perform the intermediate processes separately, makes an additive combine at last, thereby an ECC block can be obtained. Hereby, a data move via a memory is decreased, and the achievement of the speeding up and the low power consumption becomes easy.

In the generation process of the ECC block, many processes are required such as generation of an error detection-codes, generation of an error correction codes, a scramble process, and so on, thereby the writing/reading to/from a memory is required in each time. Consequently, to record a data on a recording medium, the amount of data move is increased, and the achievement of the speeding up and the low power consumption may become difficult.

2. In case when a part of data is modified, the recalculation from the first step is not necessary, and by correcting only the modified portion, the final objective data block can be obtained, and the processing performance can be improved. For example, as in a block-slip process, in case when an error detecting code is corrected by a modification of only a scramble data (or with ID), an error detecting code of the main data is not necessary to be corrected, therefore the correction of an error detecting code becomes easy.

3. On two axis syndromes in a product code, the opposite error occurrence series can be mutually used, thereby an effective error correction process can be performed.

4. An error detecting code EDC which has a role to detect a miss correction in an error correction process, can be effectively used. That is to say, a result of an EDC detection of data finally stored on a memory, can be checked in advance.

5. A PO code and a PI code only corresponding to scramble data, is recorded on a ROM or the like in advance, thereby a calculation becomes unnecessary, and further speeding up can be achieved.

### OTHER EMBODIMENTS

Embodiments of the present invention can be expanded/modified without being limited to the above-described embodiment, and such expanded/modified embodiments are also included in the technical scope of the present invention.

1. An error correction code generator, comprising:
an individual error correction code generating unit to generate the error correction codes of the respective plural blocks having one of a plurality of components composing an ECC block; and
an ECC code generating unit to generate the error correction code of the ECC block as a whole by adding the generated error correction codes.

2. The error correction code generator according to claim 1, wherein said individual error correction code generating unit including:
a first code generating unit to generate a first error correction code based on an ID data composing the ECC block;
a second code generating unit to generate a second error correction code based on a main data composing the ECC block; and
a third code generating unit to generate a third error correction code based on a scramble data composing the ECC block.

3. The error correction code generator according to claim 2, wherein the first code generating unit generates the first error correction code based on the ID data and the error detecting code of the ID data.

4. The error correction code generator according to claim 2, wherein the second code generating unit generates the second error correction code based on the main data and the error detecting code of the main data.

5. The error correction code generator according to claim 2, wherein the third code generating unit having a table representing a correspondence between the scramble data and the third error correction code.

6. The error correction code generator according to claim 2, further comprising:
a recording medium writing unit to write the ECC block having the generated error correction code of the ECC block to a recording medium;
a write judgment unit to judge whether a writing process of the ECC block by said recording medium writing unit is successful or not; and
a data modification unit to modify the ID data and the scramble data of the ECC block when said write judgment unit judges that the writing process of the ECC block is unsuccessful, and
wherein said individual error correction code generating unit further including:
a fourth code generating unit to generate a fourth error correction code based on the modified ID data; and
a fifth code generating unit to generate a fifth error correction code based on the modified scramble data, and
wherein said ECC code generating unit generates the error correction code of the ECC block as a whole by adding the second, fourth, and fifth error correction codes.

7. A disk recording device comprising the error correction code generator according to claim 1.

8. A generation method of error correction code, comprising:
generating the error correction codes of the respective plural blocks having one of a plurality of components composing an ECC block; and
generating the error correction code of the ECC block as a whole by adding the generated error correction codes.

9. The generation method of error correction code according to claim 8, wherein said generating the error correction codes of the respective plural blocks, including:
generating a first error correction code based on an ID data composing the ECC block;
generating a second error correction code based on a main data composing the ECC block; and
generating a third error correction code based on a scramble data composing the ECC block.

10. The generation method of error correction code according to claim 9, wherein the first error correction code is generated based on the ID data and the error detecting code of the ID data.

11. The generation method of error correction code according to claim 9, wherein the second error correction code is generated based on the main data and the error detecting code of the main data.

12. The generation method of error correction code according to claim 9, wherein the third error correction code is generated by using a table representing the correspondence between the scramble data and the third error correction code.

13. The generation method of error correction code according to claim 9, further comprising:
attempting to write the ECC block having the generated error correction code of the ECC block to a recording medium;
judging whether said attempting to write is successful or not; and
modifying the ID data and the scramble data of the ECC block when said attempting to write is judged as unsuccessful, and
wherein said generating the error correction codes of the respective plural blocks further including:
generating a fourth error correction code based on the modified ID data; and
generating a fifth error correction code based on the modified scramble data, and
wherein the second, fourth, and fifth error correction codes are added and the error correction code of the ECC block as a whole is generated.

14. A recording method, comprising:
generating the error correction codes of the respective plural blocks having one of a plurality of components composing an ECC block;
generating the error correction code of the ECC block as a whole by adding the generated error correction codes; and
recording the ECC block containing the generated error correction code of the ECC block to a recording medium.

15. An error correction device, comprising:
an ID detecting unit to detect an ID data from an ECC block including an error correction code;
a de-scramble unit to de-scramble the ECC block with the detected ID data; and
an error detecting unit to detect an error of the ECC block by the EDC calculation process based on the de-scrambled ECC block.

16. An error correction method, comprising:
detecting an ID data from an ECC block including an error correction code;
de-scrambling the ECC block with the detected ID data; and
detecting an error of the ECC block by the EDC calculation process based on the de-scrambled ECC block.
